(19) United States
(12) Patent Application Publication
(10) Pub. No.: US 2010/0001328 A1
(43) Pub. Date: Jan. 7, 2010

(54) SEMICONDUCTOR DEVICE HAVING AN ANTI-PAD PEELING-OFF STRUCTURE

(75) Inventors: Seung-Jin Yang, Seoul (KR); Jeong-Uk Han, Suwon-si (KR); Yong-Tae Kim, Yongin-si (KR); Yong-Suk Choi, Hwaseong-si (KR); Bae-Seong Kwon, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/498,724

(22) Filed: Jul. 7, 2009

(30) Foreign Application Priority Data
Jul. 7, 2008 (KR) 2008-65410

(51) Int. Cl. H01L 27/105; H01L 29/40; H01L 27/108; H01L 29/792

(52) U.S. Cl. 257/296; 257/368; 257/324; 257/E29.111; 257/E27.084; 257/E29.309

(57) ABSTRACT

A bonding pad having an anti-pad peeling-off structure is disclosed. In a method of forming the bonding pad, after a metal pad layer is formed, a slit is formed in the metal pad layer. A protecting layer is formed on the metal pad layer. The protecting layer is partially removed to expose the metal pad such that a portion of the protecting layer remains in the slits to be connected to the main protecting layer. The protecting layer formed in the slit is connected to the protecting layer such that the residual protecting layer pattern buffer when physical impacts are generated, to prevent peeling-off of the metal pad layer.

### CROSS-REFERENCE TO RELATED PATENT APPLICATION

This application claims priority under 35 U.S.C. § 119 from Korean Patent Application No. 10-2008-0065410, filed on Jul. 7, 2008 in the Korean Intellectual Property Office, the contents of which are herein incorporated by reference in their entirety.

### BACKGROUND

1. Field of the Invention

Methods and apparatuses consistent with exemplary embodiments of the present invention relate to a semiconductor device having an anti-pad peeling-off structure and a method of manufacturing the same. More particularly, example embodiments relate to a semiconductor device having an anti-pad peeling-off structure capable of overcoming stresses applied to a metal pad during a bonding process and a method of manufacturing the same.

2. Description of the Related Art

Generally, as semiconductor devices become highly integrated, dimensions of cells are reduced. Accordingly, it may be important to ensure physical and electrical properties of the semiconductor devices. When physical or electrical impacts occur in the unit cell, the impacts may not be buffered or distributed due to the reduced dimensions of the unit cell so that failures occur frequently in the device.

The semiconductor device includes a plurality of metal pads that connect the device in the cell to an external terminal. A metal layer on the pad is connected to a terminal pad of the inner device and is connected to a lead frame by a wiring bonding process, to be used as an electrical interconnection path. A wire or ball bonding process may generate physical stresses on the pad. If the physical stresses are not absorbed or distributed, adhesion strength between the metal pad and an underlying layer thereof is decreased, which may cause the metal pad to peel off from the underlying layer. In particular, because the metal pad includes a barrier metal layer, adhesive strength between the barrier metal layer and the underlying layer is relatively low so that the metal pad is peeled off by physical impacts or attraction force.

For example, when a capillary of a bonding apparatus adheres a gold ball to the pad and is pulled back, the metal pad is peeled off frequently.

Accordingly, disconnection problems between the semiconductor device and an external system are generated by peeling-off of the metal pad.

Referring to FIGS. 1 to 3, metal layers of bonding pads are peeled off during a wire bonding process.

Therefore, a new method of forming a pad structure having an anti-pad peeling-off structure is required.

### SUMMARY OF THE INVENTION

Example embodiments of the present invention provide a semiconductor device having an anti-pad peeling-off structure capable of overcoming stresses applied to a metal pad during a bonding process.

Example embodiments provide a method of forming the semiconductor device.

According to an aspect of the present invention, there is provided a method of manufacturing a semiconductor device in which various element patterns are formed on a semiconductor substrate. A metal pad layer is formed to be connected to the element pattern. A plurality of slits is formed in the metal pad layer. A protecting layer is formed on the metal pad layer. The protecting layer is partially removed to expose the metal pad such that a portion of the protecting layer remains in the slits to be connected to the main protecting layer.

According to an aspect of the present invention there is provided a method of manufacturing a semiconductor device, in which various element patterns are formed on a semiconductor substrate. The element pattern includes a plurality of redundant patterns that form a concavo-convex structure in a region for a metal pad to be formed. A metal pad layer is formed to be connected to the element pattern. A plurality of slits is formed in the metal pad layer. A protecting layer is formed on the metal pad layer. The protecting layer is partially removed to expose the metal pad such that a portion of the protecting layer remains in the slits to be connected to the main protecting layer.

According to another aspect of the present invention there is provided a method of manufacturing a semiconductor device in which a flash semiconductor structure is formed in a semiconductor substrate. A metal contact plug is formed under a metal pad. After the metal pad layer is formed on the metal contact plug, a plurality of slits is formed in the metal pad layer. A protecting layer is formed on the metal pad layer. The protecting layer is partially removed to expose the metal pad such that a portion of the protecting layer remains in the slits to be connected to the main protecting layer.

According to another aspect of the present invention, there is provided a method of manufacturing a semiconductor device in which a tunnel oxide layer is formed on a semiconductor substrate, a tunnel gate layer is formed on the tunnel oxide layer, and a tunnel gate is formed in the tunnel gate layer. An isolation layer is formed in the semiconductor substrate using the tunnel gate, a dielectric layer and a control gate are formed on the tunnel gate, and an insulation interlayer is formed on the control gate. Contact holes are formed in the insulation interlayer, which are filled with conductive material to form a metal pad. At least one slit is formed in the metal pad and a protecting layer is formed on the metal pad. The protecting layer is partially removed to expose the metal pad such that a portion of the protecting layer remains in the slit.

According to an aspect of the present invention, a plurality of the slits is formed in the metal pad layer and the protecting layer is formed on the slits, thereby preventing peeling-off of the metal pad layer.

The structure under the metal pad may have a concavo-convex structure capable of increasing adhesive strength with a lower surface of the metal pad layer, thereby preventing peeling-off of the metal pad layer.

Since the residual protecting layer pattern in the slits of the metal pad layer includes a material different from the metal pad layer, the residual protecting layer pattern may provide a buffer when physical impacts are generated or may terminate cracks generated in the metal pad.

Moreover, the protruding shape of the protecting layer pattern may overcome pull-back stresses during a wire bonding process, thereby preventing peeling-off of the metal pad layer.

### BRIEF DESCRIPTION OF THE DRAWINGS

Example embodiments will be more clearly understood from the following detailed description taken in conjunction with the accompanying drawings.

FIGS. 1 to 3 are electron microscopic images illustrating failures of related art metal pads.

FIGS. 4 to 9 are cross-sectional views illustrating a method of manufacturing a semiconductor device having an anti-pad peeling-off structure in accordance with a first example embodiment.

FIGS. 10 and 12 are plan views illustrating a metal pad with an anti-pad peeling-off structure in accordance with a first example embodiment.

FIGS. 13 to 19 are cross-sectional views illustrating a method of manufacturing a semiconductor device having an anti-pad peeling-off structure in accordance with a second example embodiment.

FIGS. 20 to 39 are cross-sectional views illustrating a method of manufacturing a flash memory device having an anti-pad peeling-off structure in accordance with a third example embodiment.

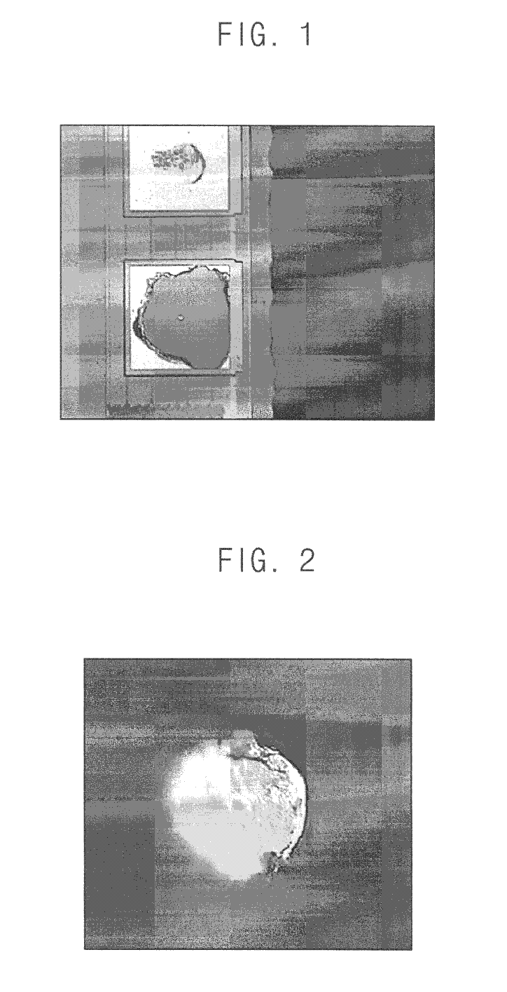

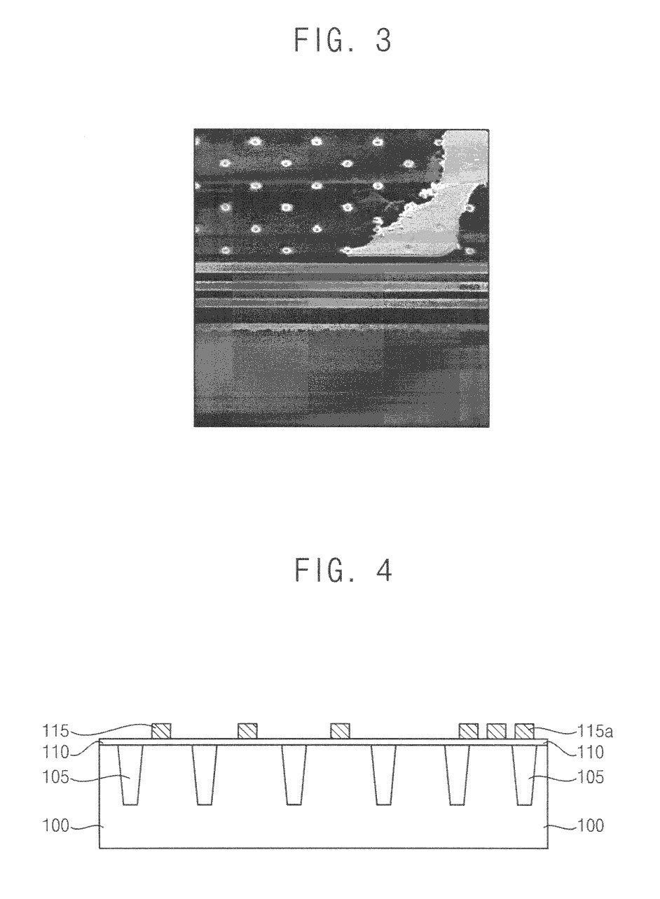

### DETAILED DESCRIPTION OF THE EXEMPLARY EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

### Embodiment 1

FIGS. 4 to 9 are cross-sectional views illustrating a method of manufacturing a semiconductor device having an anti-pad peeling-off structure in accordance with a first example embodiment.

Referring to FIG. 4, a semiconductor device according to a first example embodiment is divided into a region for elements to be formed and a region for pads to be formed. The pads may be formed in a peripheral region of the semiconductor device. Alternatively, the pads may be formed in the central region according to an arrangement of pins in a packaging process.

Hereinafter, a method of manufacturing a semiconductor device including pads formed in a right peripheral region will explained for clarity.

An isolation layer 105 is formed in a semiconductor substrate 100. The isolation layer 105 may be formed by a shallow trench isolation (STI) process or a local oxidation (LOCOS) process.

After forming the isolation layer 105, a gate dielectric layer 110 is formed on the semiconductor substrate 100. The semiconductor substrate 100 may include a silicon wafer or a silicon-on-insulator (SOI) substrate. The gate dielectric layer 110 may be formed to have a thickness of 50 Å to 100 Å by a thermal oxidation process. The gate dielectric layer 110 may be formed using a material having excellent film characteristics for reading/writing operations of the device. Accordingly, the gate dielectric layer 110 may be formed using silicon oxide or silicon oxynitride by a radical oxidation process.

Gate electrodes 115 are formed on the gate dielectric layer 110 to be used electrodes. Required numbers of the gate electrodes 115 may be formed in the region for the elements to be formed.

Redundant electrode patterns 115a are formed in the peripheral region in right of FIG. 4. The redundant electrode patterns 115a may not be required for operations of the elements. The redundant electrode patterns 115a may form a concavo-convex structure. The concavo-convex structure may increase adhesive strength with a lower surface of the metal pad layer to be formed by a following process, thereby preventing peeling-off of the metal pad layer.

In this embodiment, the redundant electrode patterns 115a may be formed together when the gate electrodes 115 are formed. Alternatively, the concavo-convex structure may be formed by an additional process according to properties of the device or process.

For example, in case that the semiconductor device is a DRAM device, electrode materials for forming capacitors may be formed to be redundant capacitor patterns, to provide the concavo-convex structure. In this case, the redundant capacitor patterns may be formed together when a capacitor electrode is formed after forming a mold layer, whereas the process of forming the gate electrodes to be provided as the redundant electrode patterns may be omitted.

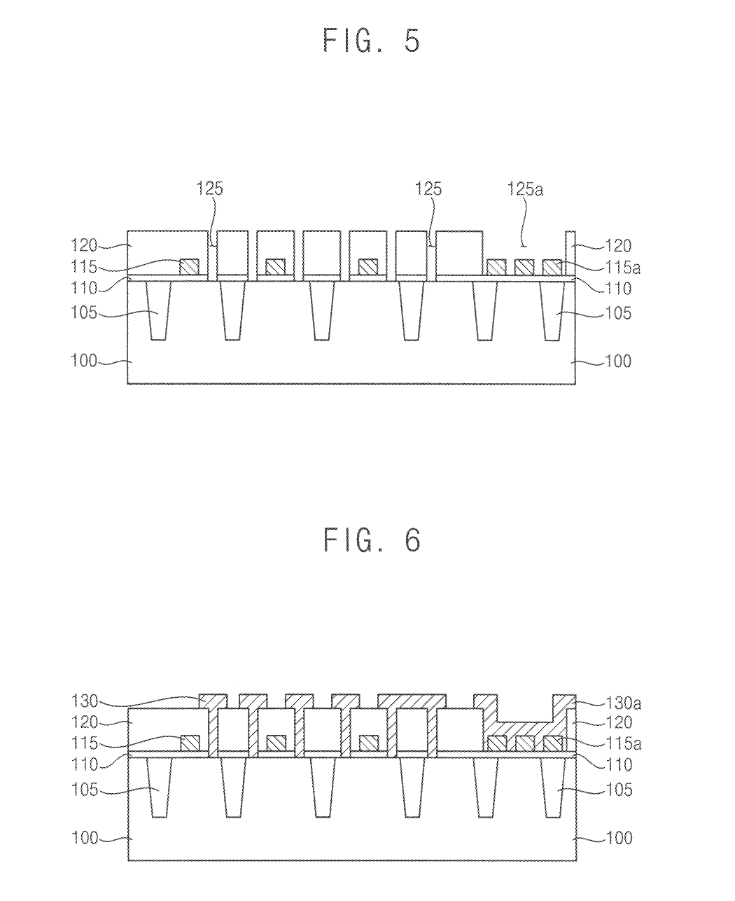

Referring to FIG. 5, an insulation interlayer 120 is formed on the semiconductor substrate 100 and the gate electrodes 115. The insulation interlayer 120 may be formed by a chemical vapor deposition (CVD) process or a high density plasma (HDP) process, and then the insulation interlayer 120 may be planarized by a chemical mechanical polishing (CMP) process. The insulation interlayer 120 has contact holes 125 that expose the electrode patterns. The contact holes 125 have a concavo-convex portion 125a due to the electrode patterns. The concavo-convex portion 125a may increase contact areas with the lower surface of the metal pad and the electrode patterns may buffer physical stresses applied to the metal pad. Accordingly, the electrode patterns may be formed using a material different from the metal pad. For example, the electrode patterns may be formed using polysilicon.

Referring to FIG. 6, a metal layer 130 is formed in the contact holes 125 and on the insulation layer 120. Forming the metal layer 130 in concavo-convex portion 125a forms metal pad 130a. The metal layer 130 may be a single-layer structure or a multi-layer structure. For example, before the metal layer 130 is formed, a barrier metal (not illustrated) may be formed in the contact holes 125 and on the insulation interlayer 120 to have a thickness of to 100 Å by a sputtering process. The barrier metal may be formed using a metal having a relatively high melting point such as Ti, TiN, TiW, Ti/TiN, etc., or metal nitride.

The barrier metal layer may prevent a high resistance occurring when the metal layer 130 makes contact with the substrate. Further, since the redundant electrode patterns 115a of the electrode patterns 115 form a concavo-convex structure, the barrier metal layer may make contact with the electrode patterns in vertical and horizontal directions, to thereby increase adhesive strength with the metal pad.

Accordingly, a structure for preventing peeling-off of the metal pad may be acquired firstly. In this embodiment, the electrode patterns including polysilicon may combine with the barrier metal layer to provide a physical structure having excellent adhesive strength.

An aluminum layer is deposited on the barrier metal layer and then patterned by a photolithography process to form a metal layer 130. In an exemplary embodiment, the metal layer 130 is a metal layer pattern. The metal layer 130 may be formed using a metal different from aluminum. The metal layer 130 may be formed to have a thickness of 5,000 Å to 10,000 Å. In an exemplary embodiment, the metal layer 130 formed in contact holes 125 is made of Tungsten, and the metal pad 130 formed in concavo-convex portion 125a is formed from Aluminum.

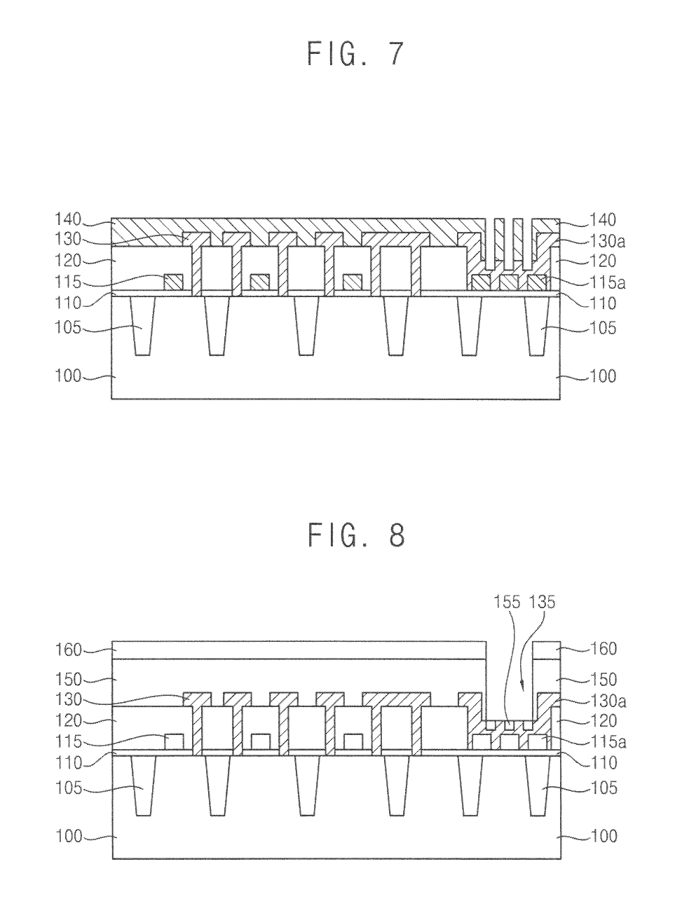

Referring to FIG. 7, a photoresist layer is formed on the metal layer 130 and patterned to form a slit mask pattern 140 having openings in the region for the pad to be formed. The metal pad 130a is etched using the slit mask pattern 140 having the openings as an etching mask to form slits in the metal pad 130a.

The metal pad 130a may be partially etched such that the slits do not penetrate the metal pad 130a to form grooves in the metal pad 130a. The height of the slit may range from 2,000 Å to 3,000 Å. The time of etching the metal pad 130a may be controlled such that the slits do not extend beyond the middle portion of the metal pad 130a.

The slits may have a structure where a material for a protecting layer remains in the slits to prevent peeling-off of the metal pad. The slits may be determined to have required dimensions for a bonding process.

After forming the slits, the slit mask pattern 140 is removed from the substrate.

Referring to FIG. 8, a protecting layer 150 is formed on the insulation interlayer 120 and the metal layer 130. The protecting layer 150 may be formed using nitride or oxide. The protecting layer 150 may have a single-layer structure or a multi layer structure. After forming the protecting layer 150, a thermal treatment process may be performed such that an alloy layer is formed in the interface between the barrier metal layer of the metal layer 130 and the gate electrodes 115 to increase adhesive strength therebetween.

A photoresist layer is coated on the protecting layer 150 and patterned to form a bonding pad mask 160 that exposes only the region for a bonding pad to be formed. The protecting layer 150 is partially removed using the bonding pad mask 160. In here, the protecting layer may be etched such that a portion of the protecting layer 155 remains in the slits of the metal pad 130a. The protecting layer 150 may be etched until an upper surface of the metal pad 130a, that is, bonding pad 135 is exposed, such that the portion of the protecting layer 155 remains in the slits.

The bonding pad 135 including the protecting layer 155 remaining in the slits may have a physical structure capable of preventing peeling-off of the bonding pad 135.

As mentioned above, after forming the bonding pad 135, the slits are formed in the metal pad 130a by an etch process using the slit mask pattern 140 as an etching mask. Then, after forming the protecting layer, the residual protecting layer pattern 155 is formed in the slits during the process of etching the protecting layer. The residual protecting layer pattern 155 has a protruding shape extending laterally from the opening of the main protecting layer 150, thereby preventing peeling-off of the metal pad 130a.

The metal pad structure including the residual protecting layer pattern with a protruding shape is different in various aspects from a related art metal pad structure where the metal pad is prevented from peeling off by the protecting layer pattern formed on the metal pad. In particular, the slits are formed in the metal pad and the protecting layer filling the slits is removed to form the residual protecting layer pattern such that the upper surface of the residual protecting layer pattern has the same height as the upper surface of the metal pad. Accordingly, the residual protecting layer pattern may not make troubles during a following bonding process.

Further, since the residual protecting layer pattern in the slits of the metal pad includes a material different from the metal pad, the residual protecting layer pattern may provide a buffer when physical impacts are generated or may terminate crack generated in the metal pad.

The metal pad structure according to a first example embodiment may more effectively prevent peeling-off of the metal pad than a related art metal pad structure.

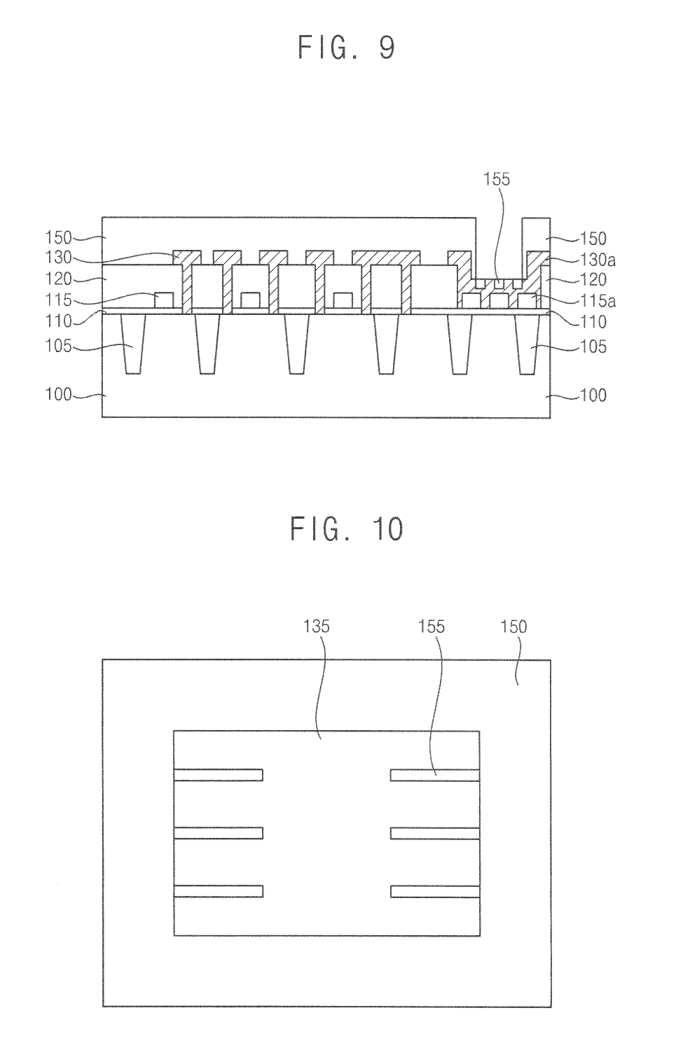

Referring to FIG. 9, the bonding mask 160 is removed from the substrate. Accordingly, the bonding region of the bonding pad 135 is exposed and the other region of the bonding pad 135 is covered with the protecting layer. The residual protecting layer pattern 155 is formed in the slits in the bonding region such that the residual protecting layer 155 extends to be connected to the main protecting layer 150. The upper surface of the residual protecting layer pattern has the same height as the upper surface of the metal pad. The residual protecting layer pattern 155 has a protruding shape. The protruding shape of the residual protecting layer pattern 155 extends laterally in the slits to be connected to the sidewall of the protecting layer 150 and supported by the main protecting layer 150.

The residual protecting layer pattern 155 in the slits may overcome stresses applied to the metal pad during a bonding process together with the main protecting layer 150, thereby preventing peeling-off of the metal pad. Further, the residual protecting layer pattern including a material different from the metal pad may terminate crack generated in the metal pad. The gate electrodes 115 having the concavo-convex structure 115a combine with the metal pad 130a to form an alloy layer, to thereby increase adhesive strength therebetween and buffer when physical impacts are generated during the bonding process.

According to this embodiment, the metal pad structure includes a lower portion of polysilicon having the concavo-convex structure and an upper portion of the metal pad having the protecting layer pattern in the slits formed therein, to preventing peeling-off of the metal pad.

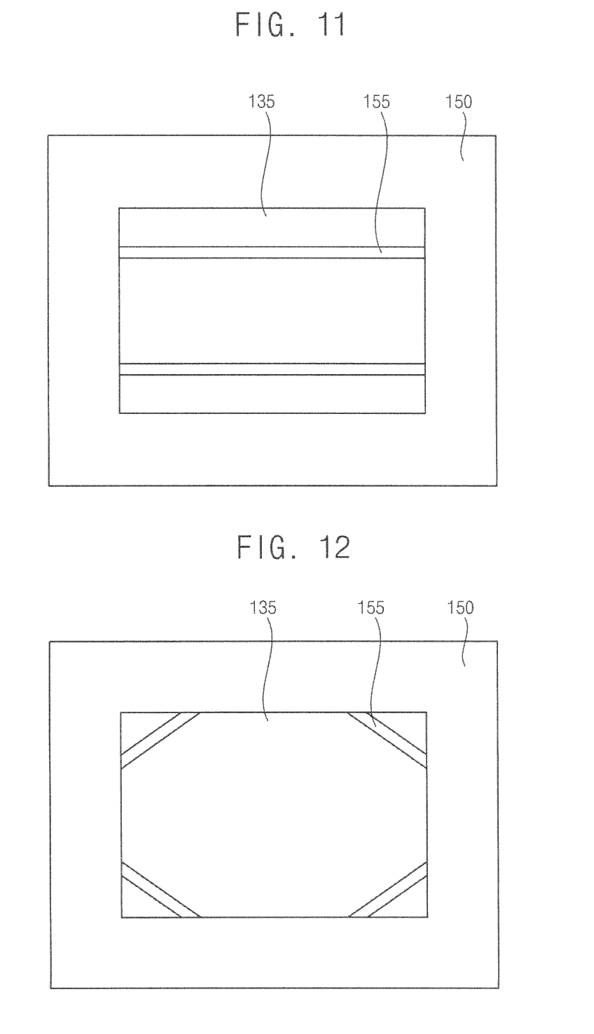

FIG. 10 is a plan view illustrating the relationship between the bonding pad 135, the main protecting layer 150 and the protecting layer pattern 155 in the slits in the bonding region in accordance with an example embodiment.

As mentioned above, the protecting layer pattern 155 has a horizontal bar shape. An end portion of the protecting layer pattern 155 is connected to the main protecting layer 150 to have the protruding shape. The protruding shape of the protecting layer pattern 155 may overcome pull-back stresses during a wire bonding process, thereby preventing peeling-off of the metal pad 130a.

FIGS. 11 and 12 are plan views illustrating the relationship between the bonding pad 135, the main protecting layer 150 and the protecting layer pattern 155 in the slits in the bonding region in accordance with another exemplary embodiment.

The slits are arranged parallel with each other to have a parallel bar shape. Both end portions of the residual protecting layer pattern 155 in the slits are connected to the main protecting layer 150 to have an H-shape.

The protecting layer pattern 155 may be a middle connection bar of the H-shape and the main protecting layer 150 may be both pillars of the H-shape.

The H-shaped structure where both end portions thereof are connected to the main protecting layer 150 may overcome pull-back stresses during a wire bonding process, thereby preventing peeling-off of the metal pad 130.

The slits may be formed to have various structures according to dimensions and positions of a wire or a ball during a bonding process. Besides the aforementioned embodiments, the slits may be formed to have a mesh or net shape. It should be understood that the slits are formed to have various shapes in combination thereof.

Exemplary embodiments should not be construed as limited to the particular shapes of the slits illustrated herein. Rather, exemplary embodiments are provided so that the slits having various shapes are formed in the metal pad and then the residual protecting layer pattern 155 in the slits is formed to be connected to the main protecting layer 150 to distribute or overcome stresses, to thereby provide a semiconductor device having an anti-pad peeling-off structure.

### Embodiment 2

FIGS. 13 to 19 are cross-sectional views illustrating a method of manufacturing a semiconductor device having an anti-pad peeling-off structure in accordance with a second exemplary embodiment.

Referring to FIG. 13, a semiconductor device according to a second exemplary embodiment is divided into a region for elements to be formed and a region for pads to be formed. The pads may be formed in a peripheral region of the semiconductor device. Alternatively, the pads may be formed in the central region according to an arrangement of pins in a packaging process.

Hereinafter, a method of manufacturing a semiconductor device including pads formed in a right peripheral region will be explained for clarity.

An isolation layer 205 is formed in a semiconductor substrate 200. The isolation layer 205 may be formed by a STI process or a LOCOS process.

After forming the isolation layer 205, a gate dielectric layer 210 is formed on the semiconductor substrate 200. The semiconductor substrate 200 may include a silicon wafer or a SOI substrate. The gate dielectric layer 210 may be formed to have a thickness of 50 Å to 100 Å by a thermal oxidation process. The gate dielectric layer 210 may be formed using a material having excellent film characteristics for reading/writing operations of the device. Accordingly, the gate dielectric layer 210 may be formed using silicon oxide or silicon oxynitride by a radical oxidation process.

Gate electrodes 215 are formed on the gate dielectric layer 210 to be used as an electrode. Although it is not illustrated in the figure, after forming the electrodes, an impurity region having a relatively low concentration, a spacer for the gate electrode and an impurity region having a relatively high concentration are formed on the substrate.

Required numbers of the gate electrodes 215 may be formed in the region for the elements to be formed.

Redundant electrode patterns 115a in Embodiment 1 are not formed in the pad region. Since, in this embodiment, a metal layer for a metal pad is formed using second or third metal layer, generally required numbers of the gate electrodes 215 may be formed in the pad region. For example, the gate electrodes may be formed to be spaced apart by a predetermined distance and the gate electrodes may be formed to be arranged at regular intervals.

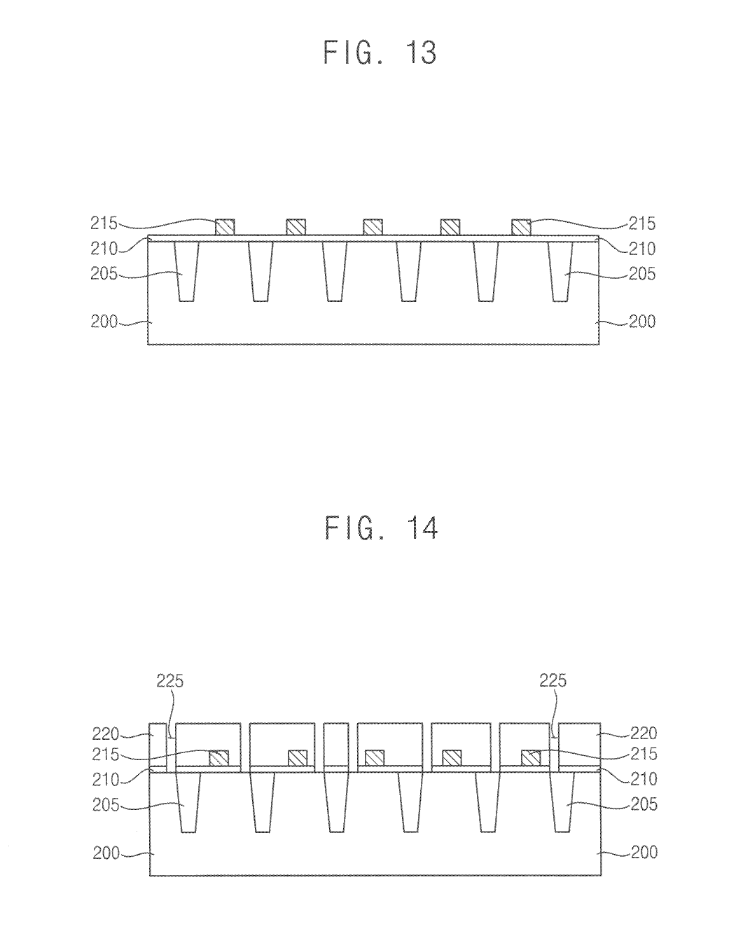

Referring to FIG. 14, a first insulation interlayer 220 is formed on the substrate 200 and the gate electrode 215. The insulation interlayer 220 may be formed by a CVD process or a HDP process, and then the insulation interlayer 220 may be planarized by a CMP process. The insulation interlayer 220 is partially etched to form first contact holes 225.

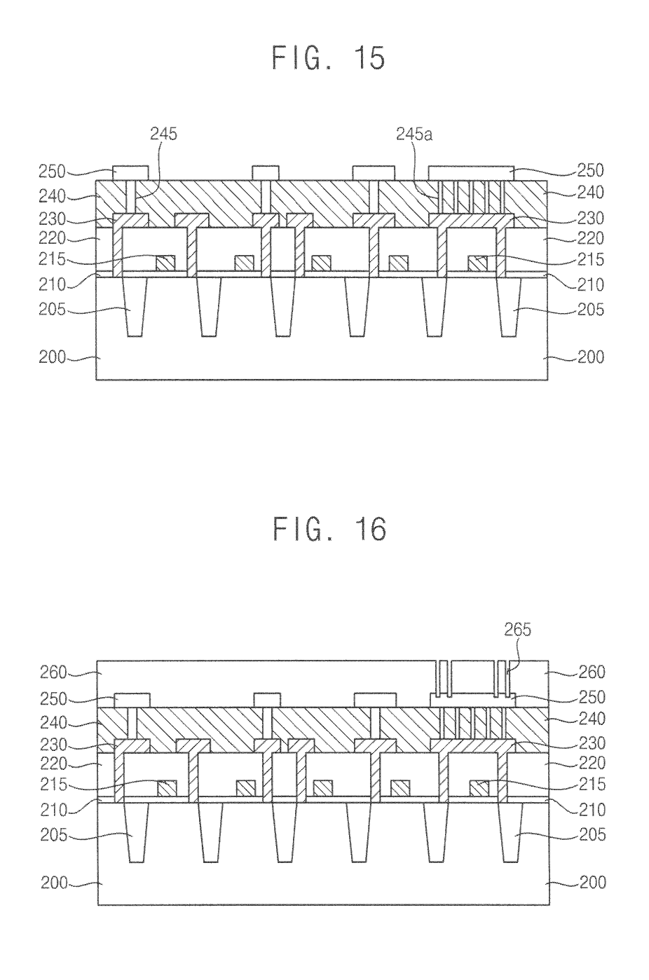

Referring to FIG. 15, a first metal layer 230 is formed in the first contact holes 225 and on the first insulation interlayer 220. The first metal layer 230 may be a single-layer structure or a multi-layer structure. For example, before the metal layer 230 is formed, a barrier metal (not illustrated) may be formed in the first contact holes 225 and on the first insulation interlayer 220 to have a thickness of to 100 Å by a sputtering process. The barrier metal may be formed using a metal having a relatively high melting point such as Ti, TiN, TiW, Ti/TiN, etc., or metal nitride.

A metal layer including aluminum, tungsten, copper, etc is formed on the barrier metal layer to fill the first contact holes 225, to form the first metal layer pattern 230. When the metal layer is formed using aluminum or tungsten, the first metal layer pattern 230 may be formed by a sputtering process. Alternatively, when the metal layer is formed using copper, the first metal layer pattern 230 may be formed by a damascene process.

The first metal layer 230 may be a multi layer structure including a lower metal layer filling the first holes 225 and an upper metal layer having a material different from the lower metal layer.

The first metal layer pattern 130 may be formed to have a thickness of 5,000 Å to 10,000 Å. The first metal layer pattern 130 formed in the pad region may have an area relatively greater than other regions to distribute stresses of the metal pad to be formed.

A second insulation interlayer 240 is formed on the first metal layer 230. The second insulation interlayer 240 may be formed by a CVD process or a HDP process, and then the second insulation interlayer 240 may be planarized by a CMP process. The second insulation interlayer 240 is partially etched to form second contact holes 245.

A plurality of the second holes 245a is formed in the second insulation interlayer 240 in the pad region. A metal layer is formed in the plurality of the second holes 245a and a second metal layer is formed on the metal layer filling the second holes, to thereby increase adhesive strength.

A barrier metal (not illustrated) may be formed in the second contact hole and on the second insulation interlayer 240 to have a thickness of to 100 Å by a sputtering process. The barrier metal may be formed using a metal having a relatively high melting point such as Ti, TiN, TiW, Ti/TiN, etc., or metal nitride.

A metal layer including aluminum, tungsten, copper, etc is formed on the barrier metal layer to fill the second contact hole, to form the second metal layer pattern 250. The second metal layer may be a multi layer structure including a lower metal layer filling the second hole and an upper metal layer having a material different from the lower metal layer. For example, the upper metal layer of the second metal layer pattern 250 may be formed using aluminum.

In this embodiment, the lower metal layer filling the second hole may be formed using tungsten and the upper metal layer may be formed using aluminum such that an alloy layer is formed in the interface therebetween increase adhesive strength.

Referring to FIG. 16, a photoresist layer is formed on the second insulation interlayer 240 and the second metal layer pattern 250, and then, is patterned to form a slit mask pattern 260.

The second metal layer pattern 250 is etched using the slit mask pattern 260 as an etching mask to form a plurality of slits 265. The plurality of the slits 265 may form grooves in the second metal layer pattern 250. The height of the slit may range from 3,000 Å to 5,000 Å. The time of etching the second metal layer pattern 265 may be controlled such that the slits do not extend beyond the middle portion of the second metal layer pattern 250. As a depth and a width of the slit 265 are increased, effects of anti-peeling off may be increased while dimensions of the contact area with the metal pad may be reduced to affect maximization of resistances and bonding areas. Accordingly, the etching time may be determined, considering the effects by the depth of the slit.

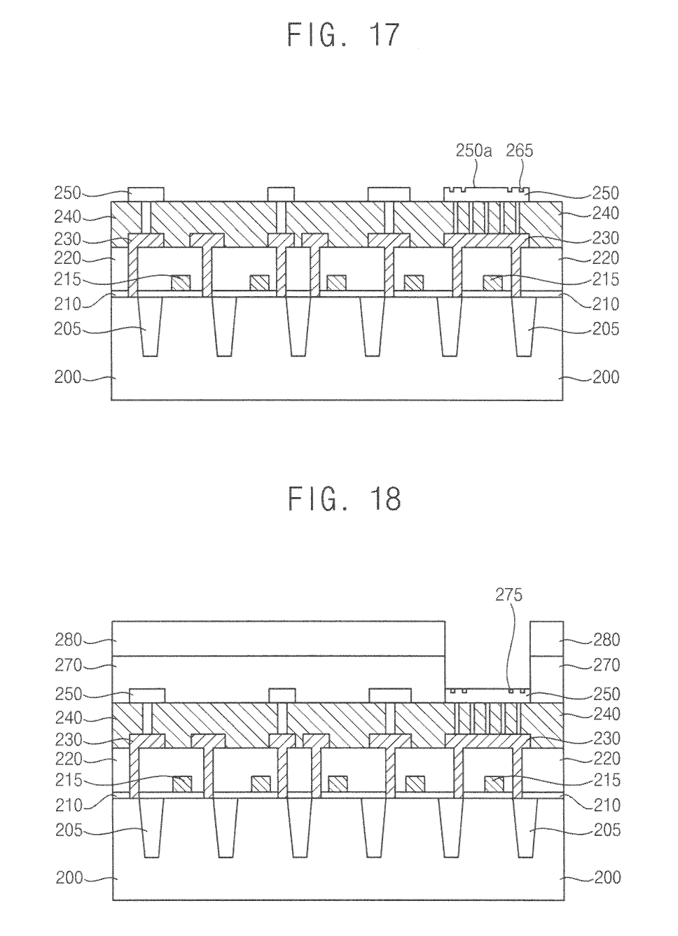

Referring to FIG. 17, after forming the slits 265, the slit mask pattern 260 is removed from the substrate. The plurality of the slits 265 are formed in an upper portion of the second metal layer pattern 250, or metal pad 250a, and the metal layer filling the second holes vertically is combined with a lower portion of the metal pad 250a.

Referring to FIG. 18, a second protecting layer 270 is formed on the second insulation interlayer 240 and the second metal layer pattern 250. The second protecting layer 270 may have a single-layer structure or a multi layer structure.

A photoresist layer is coated on the second protecting layer 270 and patterned to form a bonding pad mask 280 that exposes only the region for a bonding pad to be formed. The second protecting layer 270 is partially removed using the bonding pad mask 280. The second protecting layer may be etched such that a portion of the protecting layer 275 remains in the slits 265 of the metal pad 250.

The bonding pad including the protecting layer 275 remaining in the slits 265 may have a physical structure capable of preventing peeling-off of the metal pad 250a.

As mentioned above, after forming the metal pad 250a, the slits 265 are formed in the metal pad 250a by an etch process using the slit mask pattern 260 as an etching mask. Then, after forming the protecting layer 270, the residual protecting layer pattern 275 is formed in the slits during the process of etching the protecting layer.

The metal pad structure including the residual protecting layer pattern with a protruding shape is different in various aspects from a related art metal pad structure where the metal pad is prevented from peeling off by the protecting layer pattern formed on the metal pad. In particular, the slits are formed in the metal pad and the protecting layer filling the slits is removed to form the residual protecting layer pattern such that the upper surface of the residual protecting layer pattern has the same height as the upper surface of the metal pad. Accordingly, the residual protecting layer pattern may not cause problems during a following bonding process.

Further, since the residual protecting layer pattern in the slits of the metal pad includes a material different from the metal pad, the residual protecting layer pattern may provide a buffer when physical impacts are generated or may terminate crack generated in the metal pad.

The metal pad structure according to a second exemplary embodiment may more effectively prevent peeling-off of the metal pad than a related art metal pad structure.

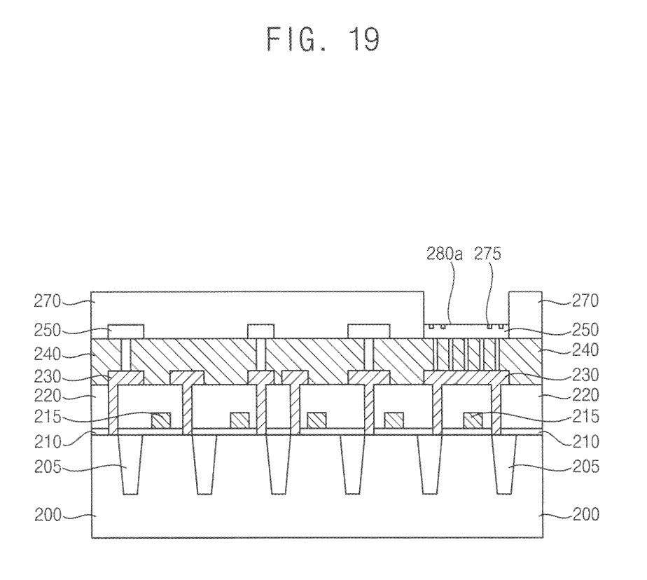

Referring to FIG. 19, the bonding mask 280 is removed from the substrate. Accordingly, the bonding region of the bonding pad 280a is exposed and the other region of the bonding pad is covered with the protecting layer. The residual protecting layer pattern 275 is formed in the slits 265 in the bonding region such that the residual protecting layer pattern 275 extends to be connected to the main protecting layer 270. The upper surface of the residual protecting layer pattern has the same height as the upper surface of the metal pad.

The residual protecting layer pattern 275 in the slits may overcome stresses applied to the metal pad during a bonding process together with the main protecting layer 270, thereby preventing peeling-off of the metal pad. Further, the residual protecting layer pattern including a material different from the metal pad may terminate cracks generated in the metal pad.

Further, the lower portion of the metal pad 250a is connected to the metal pillars filling the plurality of the second contact holes to be combined with each other, to thereby increase adhesive strength therebetween and prevent peeling-off of the metal pad 250a.

The slits may be formed to have the same shapes as illustrated in FIGS. 10 to 12 in Embodiment 1.

### Embodiment 3

FIGS. 20 to 39 are cross-sectional views illustrating a method of manufacturing a flash memory device having an anti-pad peeling-off structure in accordance with a third exemplary embodiment.

Referring to FIG. 20, in a method of forming a flash memory device according to a third exemplary embodiment, a tunnel oxide layer 305, an electrode layer 310 and a hard mask layer 315 are sequentially formed on a substrate 300. The substrate 300 may include a silicon wafer or a SOI substrate.

In this embodiment, the substrate may be divided into a region A for memory cells to be formed and a region B for peripheral circuits such as high voltage transistors to be formed. Slits may be formed on the peripheral region B.

The tunnel oxide layer 305 may be formed to have a thickness of 50 Å to 100 Å by a thermal oxidation process. The tunnel oxide layer 305 may be formed using a material having excellent film characteristics for reading/writing operations of the device. Accordingly, the tunnel oxide layer 305 may be formed by a radical oxidation process.

The floating gate electrode layer 310 may be formed using polysilicon by a CVD process. The floating gate electrode layer 310 may be formed to have a thickness of 500 Å to 1,500 Å. The floating gate electrode layer 310 may have a multi layer structure. For example, a first electrode layer may be formed to have a thickness of 300 Å and then a second electrode layer may be formed on the first electrode layer to form the floating gate electrode 310 having excellent film characteristics.

Although the hard mask layer 315 having a single layer structure is illustrated in the figure, the hard mask layer 315 may have a multi layer structure. For example, the hard mask layer 315 may include a lower layer such as an oxide layer or nitride layer, an organic layer on the lower layer and an anti-reflective layer such as a nitride layer.

Although it is not illustrated in the figure, before forming the structure in FIG. 20, impurities are implanted respectively into the MOS transistor cell region A and the peripheral region B of the substrate 300 according to respective operating voltages of the flash memory device. Further, respective wells for n-type and p-type are formed in the substrate 300 for a complementary device.

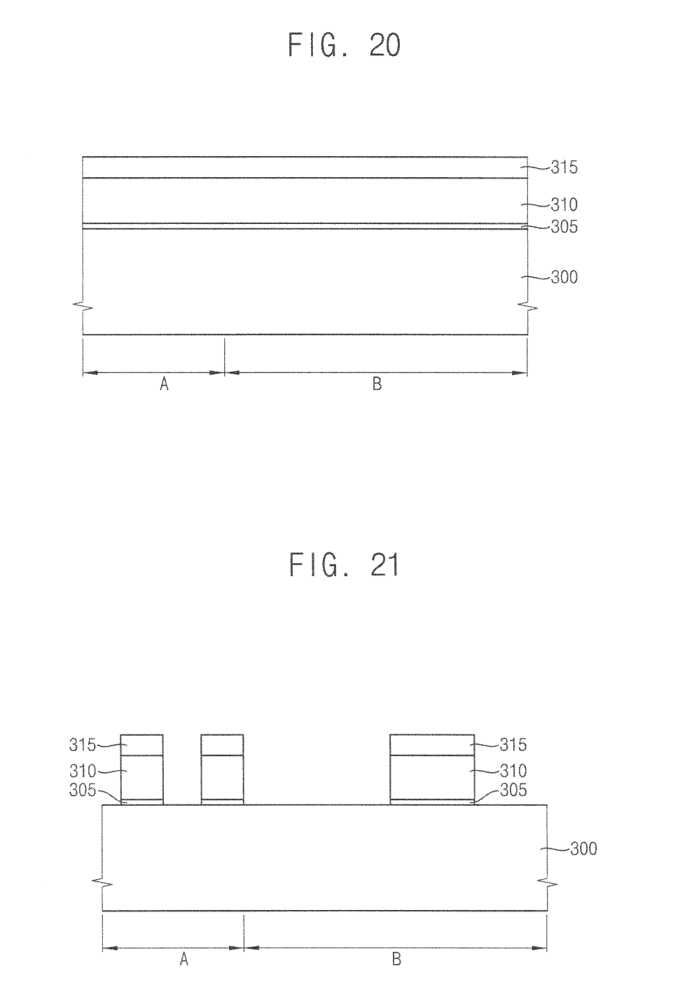

Referring to FIG. 21, the floating gate electrode pattern 310 is formed on the substrate by a photolithography process. A photoresist pattern (not illustrated) is formed on the substrate, and then the hard mask layer is etched using the photoresist pattern as an etching mask to form a hard mask layer pattern 315. Then, the floating gate electrode layer including polysilicon is etched using the hard mask layer pattern 315 as an etching mask to form a floating gate electrode pattern 310. Isolation layers may be formed in the substrate exposed by the gate electrode patterns 310 by a following process. The distance between the adjacent floating gate electrode patterns 310 formed in the memory cell region A may be smaller than the distance between the adjacent floating gate electrode patterns 310 in the peripheral region B. The gate electrode patterns may be formed in both the cell region A and the peripheral region B at once by an etching process.

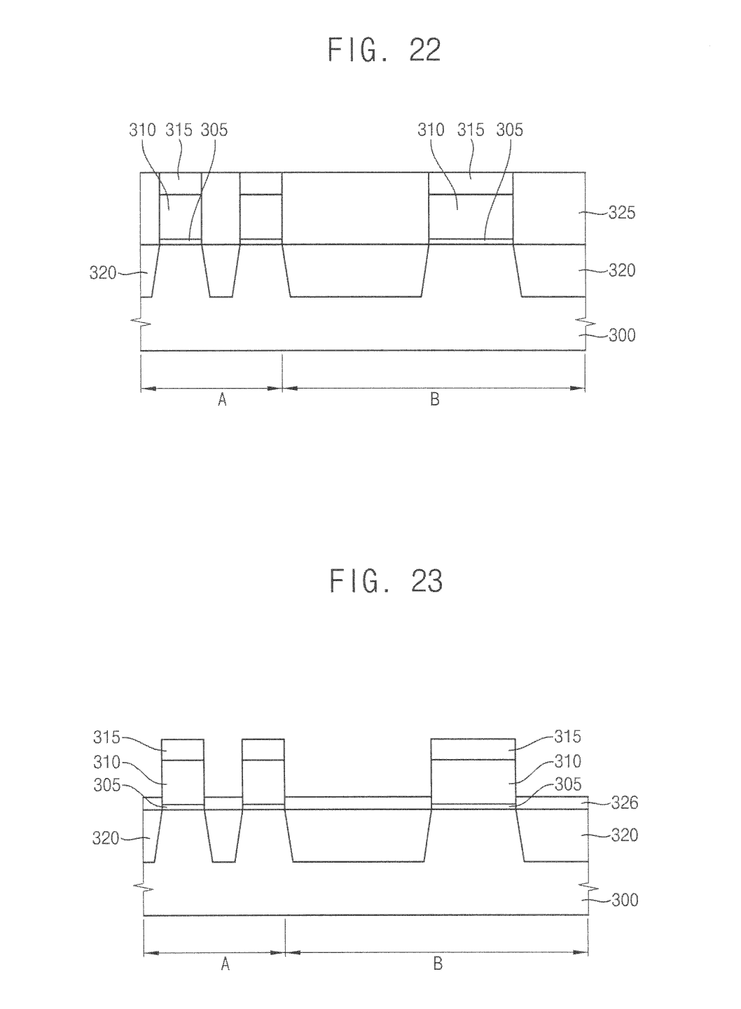

Referring to FIG. 22, the substrate 300 is partially etched using the floating gate structure as an etching mask to form trenches in the substrate 300. A sidewall of the trench may have a predetermined inclination angle such that the trench is sufficiently filled with an insulating material and stresses between the insulating material and the substrate are distributed not to focus on the channel of the device. The trench may be filled with polysiloxane by a spin-on-glass (SOG) process. Alternatively, as illustrated in FIG. 22, the trench may be filled with undoped silicate glass (USG) repeatedly at least once without generating a void and then the USG material may be planarized by an etch back process to have the same height as the substrate. Then, the upper portion of the trench may be filled with a high density plasma (HDP)-CVD oxide layer 325 and the HDP-CVD oxide layer 325 may be planarized by a CMP process. The depth of the trench may range from 2,000 Å to 5,000 Å according to required characteristics of the device. Further, in order to increase isolation effects, field ion impurities may be implanted into the substrate before forming the trenches.

Referring to FIG. 23, after the isolation layer 325 filling the trench is planarized by a CMP process, the isolation layer 325 is etched by an etch back process to form an upper isolation layer 326 having a predetermined height from the substrate. The upper isolation layer 326 may provide a spacer for a wing spacer to be formed on a sidewall of the floating gate electrode by a following process. The wing spacer may be used to require a structure capable of increasing a coupling ratio of the flash memory device.

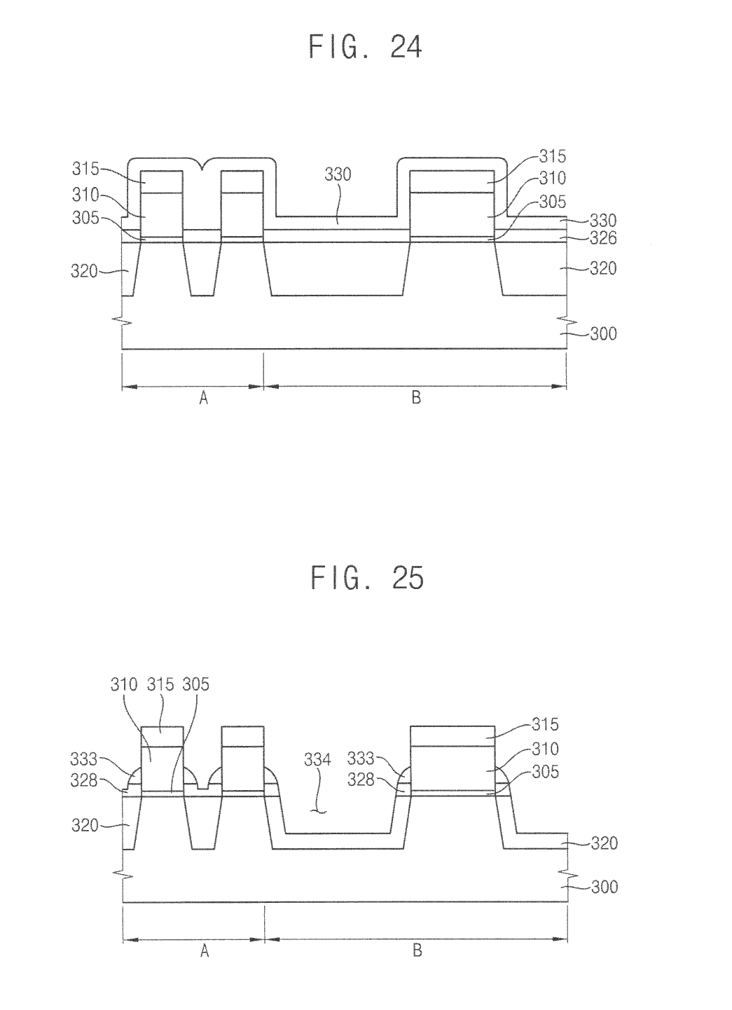

Referring to FIG. 24, a spacer layer 330 for a wing spacer is formed on the floating gate structure and the upper isolation layer 326. The spacer layer 330 may be formed by a CVD process. Due to the distance differences between the floating gate structures in the cell region A and the peripheral region B, for example, the space between the adjacent floating gate structures in the cell region A is completely filled with the spacer layer 330 while the space between the adjacent floating gate structures in the peripheral region B is partially filled with the spacer layer 330 by a thickness of the spacer layer 330. Because of these thickness differences of the spacer layer 330 filling the spaces between the adjacent floating gate structures in the cell region A and the peripheral region B, a recess may be formed in the isolation layer 320 in the peripheral region B by a following process of forming the wing spacer. The spacer layer 330 may be formed using a material having an etch selectivity with respect to the isolation layer 320 such that the recess is formed in the isolation layer 320 in the peripheral region B together when the wing spacer is formed. For example, the spacer layer 330 may be formed using a middle temperature oxide (MTO) layer.

Referring to FIG. 25, the spacer layer 330 is anisotropically etched to form a wing spacer 333 on the sidewall of the floating gate 310. In here, due to the thickness differences of the spacer layer 330 filling the spaces between the adjacent floating gate structures in the cell region A and the peripheral region B, the upper isolation layer 328 in the cell region A is partially etched while the isolation layer 320 in the peripheral region B is partially etched to form a recess 334 in the isolation layer 320 in the peripheral region B. A shield plate may be formed in the recess 334 by a following process. If a high voltage is applied to a high voltage MOS transistor adjacent to the shield plate and a ground voltage such as zero or minus voltage is applied to the shield plate, an inversion region between the high voltage MOS transistor and the surface of the isolation layer may be reduced and thus insulation breakdown characteristics may be prevented to thereby reduce problems of the device such as leakages or malfunctions in the device.

Accordingly, since the shield field depends on the distance between the shield plate and the high voltage MOS transistor, the position of the shield plate may be required to be controlled. For example, the shield plate may be formed adjacent to the bottom of the trench under the middle portion of the isolation layer 320. The shield field plate may be formed under the surface of the substrate. If the trench is formed deeply, the shield plate may be formed to be far away from the channel of the high voltage MOS transistor, to thereby reduce the shield field effect. Accordingly, the position of the shield plate may be controlled considering the depth of the trench and the distance with the adjacent high voltage MOS transistor.

As mentioned above, the wing spacer 333 may be formed on the sidewall of the floating gate 310 to increase a coupling ratio of the flash memory device. The coupling ratio of the device may depend on various factors. For example, the coupling ratio may be in proportion to the sum of the capacitance of the tunnel gate and the capacitance of the control gate and may be in inverse proportion to the capacitance of the control gate. Accordingly, when the contact area with the control gate is greater than that with the tunnel gate, the coupling ratio is increased. Therefore, the wing spacer 333 may be formed to have a structure of improving the coupling ratio.

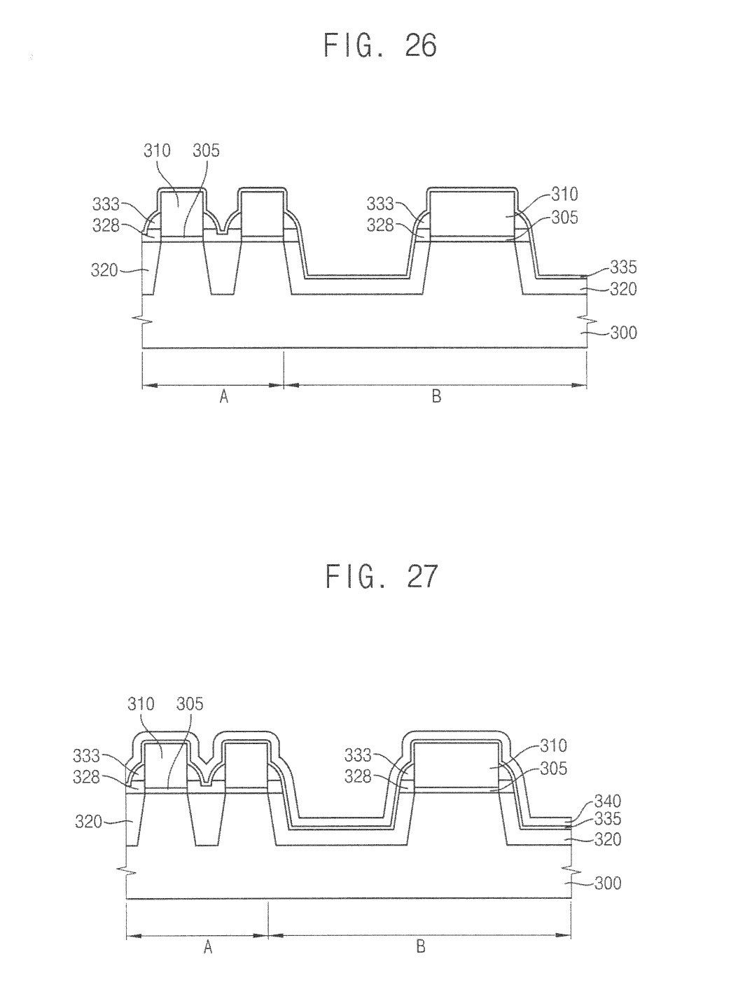

Referring to FIG. 26, an insulation interlayer 335 is formed on the floating gate electrode 310 and the isolation layer 320. The insulation interlayer 335 may be formed using a material having a dielectric constant greater than the tunnel oxide layer 305. Examples of the material may be an oxide-nitride-oxide (ONO) material or a ferroelectric material such as aluminum oxide layer, hafnium oxide layer, etc. The insulation interlayer 335 having a dielectric constant greater than the tunnel oxide layer 305 may increase the coupling ratio of the device. The thickness of the insulation interlayer 335 may range from 100 Å to 200 Å. The insulation interlayer 335 may have a single layer structure or a multi layer structure. The insulation interlayer 335 may be formed to have a stacked structure of a lower layer, a middle layer and an upper layer, to increase the dielectric constant thereof.

Referring to FIG. 27, a first control gate layer 340 for a control gate is formed on the insulation interlayer 335. The first control gate layer 340 may be formed using polysilicon by a CVD process and impurities may be implanted into the first control gate layer 340. The thickness of the first control gate layer 340 may range from 1,000 Å to 2,000 Å.

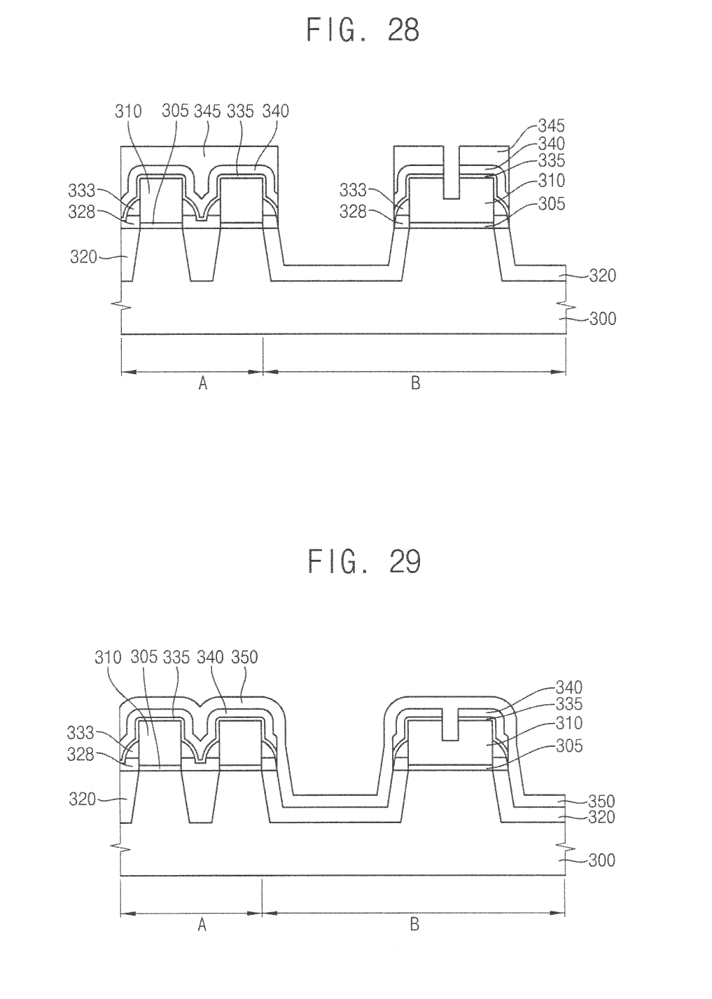

Referring to FIG. 28, the first control gate layer 340 is partially removed to form a butting mask 345. The butting mask 345 is formed to cover the floating gate 310. The butting mask 345 on the floating gate 310 in the peripheral region B has an opening that exposes the first control gate 340. The first control gate layer 340 and the insulation interlayer 335 on the floating gate 310 in the peripheral region B are partially removed using the butting mask 345, and then an upper portion of the floating gate 310 is partially removed using the butting mask 345. The first control gate layer 340 and the insulation interlayer 335 on the insulation interlayer 320 in the peripheral region B are removed using the butting mask 345. Since the transistor formed in the peripheral region B does not use tunneling, a control gate to be formed by a following process is connected to the floating gate 310 by butting, to be provided as one electrode. Accordingly, after forming the control gate layer, the transistor to be formed in the peripheral region B may be provided as a general transistor without using the tunneling effect. In addition, the first control gate layer 340 and the insulation interlayer 335 on the insulation interlayer 320 in the peripheral region B are removed to determine the height of the shield plate to be formed by a following process

Referring to FIG. 29, after the butting mask 345 is removed from the substrate, a second control gate layer 350 is formed to cover the first control gate layer. The second control gate layer 350 may be formed using polysilicon. The second control gate layer 350 may be formed using polysilicon by a CVD process and impurities may be implanted into the second control gate layer 350. The thickness of the second control gate layer 350 may range from 500 Å to 1,000 Å. In here, the second control layer 350 is formed in the butting space in the peripheral region B to be connected to floating gate 310.

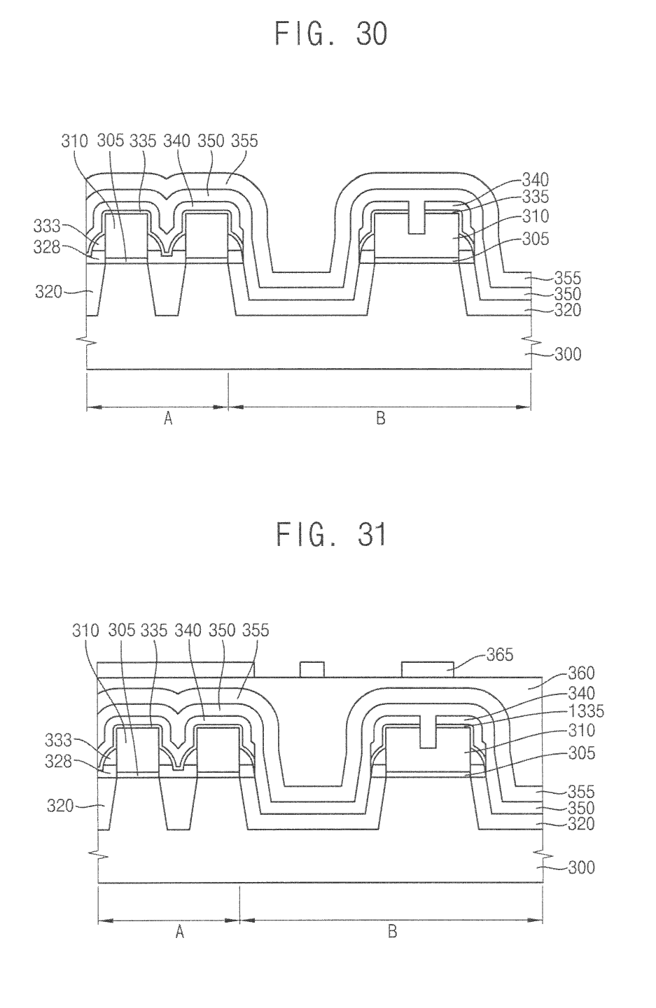

Referring to FIG. 30, a control gate metal layer 355 is formed on the second control gate layer 350. For example, the control gate metal layer 355 may be formed using tungsten silicide by a CVD process to have a thickness of from 500 Å to 1,000 Å. Then, a thermal treatment may be performed on the first and second control gate layers and the control gate metal layer 355 to improve coherence and electrical properties. The thermal treatment may be performed under 850° C. at atmosphere of nitrogen.

Referring to FIG. 31, a gate hard mask layer 360 is formed on the control gate metal layer 355. Although the gate hard mask layer having a single layer structure is illustrated in the figure, the gate hard mask layer 360 may have a multi layer structure with different material layers. For example, a lower layer of the multi layer structure may be formed using a plasma CVD oxide layer to have a thickness of from 2,000 Å to 3,000 Å, a middle layer may be formed using an organic layer such as an amorphous carbon layer (ACL) layer to have a thickness of from 2,000 Å to 3,000 Å and an upper layer may be formed using an anti-reflective layer such as a nitride layer to a thickness of about 500 Å. The gate hard mask layer 360 on the isolation layer 320 in the peripheral region B may have a thickness greater than the gate hard mask layer 360 on the floating gate 310. Accordingly, the gate hard mask layer 360 may be formed to have a stepped portion due to the height difference, although the gate hard mask layer 360 having an even surface is illustrated in the figure. Then, a photoresist pattern 365 is formed on the gate hard mask layer 360 by a photolithography process.

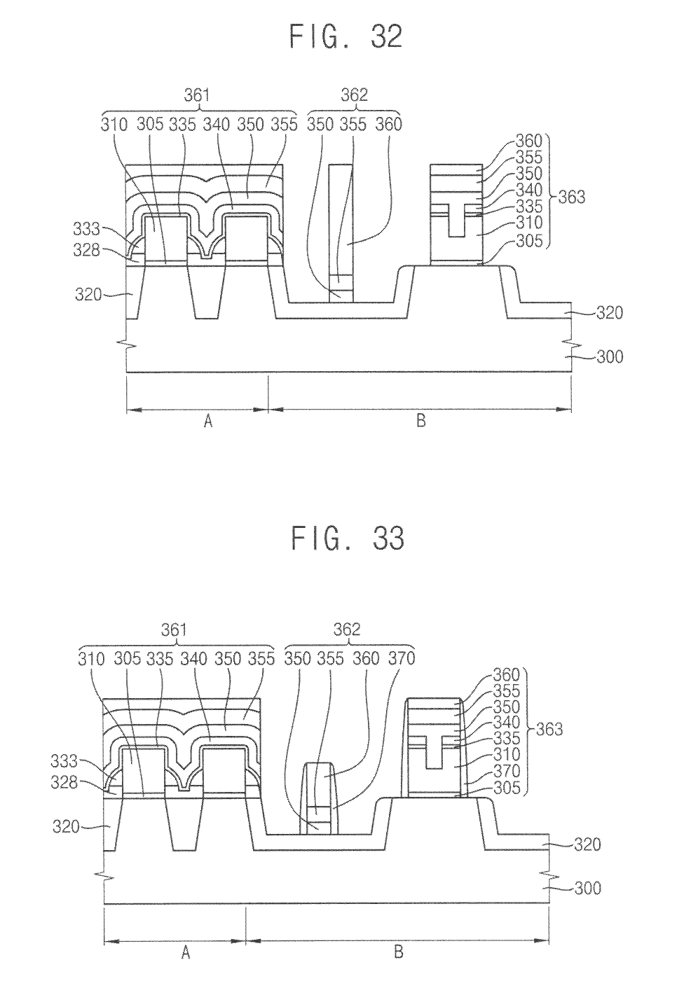

Referring to FIG. 32, the gate hard mask layer 360 is etched using the photoresist pattern 365 and then the underlying layers are etched using the patterned gate hard mask 360. The etch process may be performed until the isolation layer 320 and the substrate 300 are exposed. Thus, a cell transistor structure 361 is formed in the cell region A and a shield plate structure 362 and a high voltage transistor 363 are formed in the peripheral region B. The shield plate structure 362 includes the second control gate layer 350, the control gate metal layer 355 and the gate hard mask layer 360. For example, the gate hard mask 360 may include an oxide layer, an organic layer and an anti-reflective layer. Because the oxide layer of the gate hard mask layer has a thickness according to the underlying structure, if the organic layer and the anti-reflective layer are removed, the height of the gate hard mask layer is reduced.

Further, the wing spacer 333 and a portion of the electrode sidewall are removed by the etching process. Because the insulation interlayer for the tunneling effect is removed, the high voltage transistor structure 363 may function as a general MOS transistor.

A plurality of the memory string structures 361 may be formed in the memory cell region A. Although it is not illustrated in the figure, a low concentration source/drain impurity layers may be formed in the substrate 300 in both sides of the gate electrode.

Referring to FIG. 33, the organic layer and the anti-reflective layer are removed from the gate hard mask 360. Accordingly, the gate hard mask 360 may include only the plasma CVD oxide layer. As the organic layer and the anti-reflective layer are removed, the height of the shield plate structure 362 is reduced greatly. As mentioned above, because the thickness of the oxide layer of the gate hard mask layer 360 varies with the underlying structure, the remaining hard mask layer 360 of the shield plate may have different heights according to the underlying structure.

A spacer 370 is formed on sidewalls of the electrode and the shield plate. Similarly with the wing spacer, a spacer layer may be deposited and then may be anisotropically etched to form the spacer 370. A high impurity source/drain region may be formed using the spacer as an ion implanting mask. Accordingly, the thickness of the spacer 370 may be determined considering a required design rule of the device. The spacer 370 may be formed using a MTO layer to have a thickness of 1,000 Å.

Then, although it is not illustrated in the figure, a high impurity source/drain region may be formed in the substrate 300.

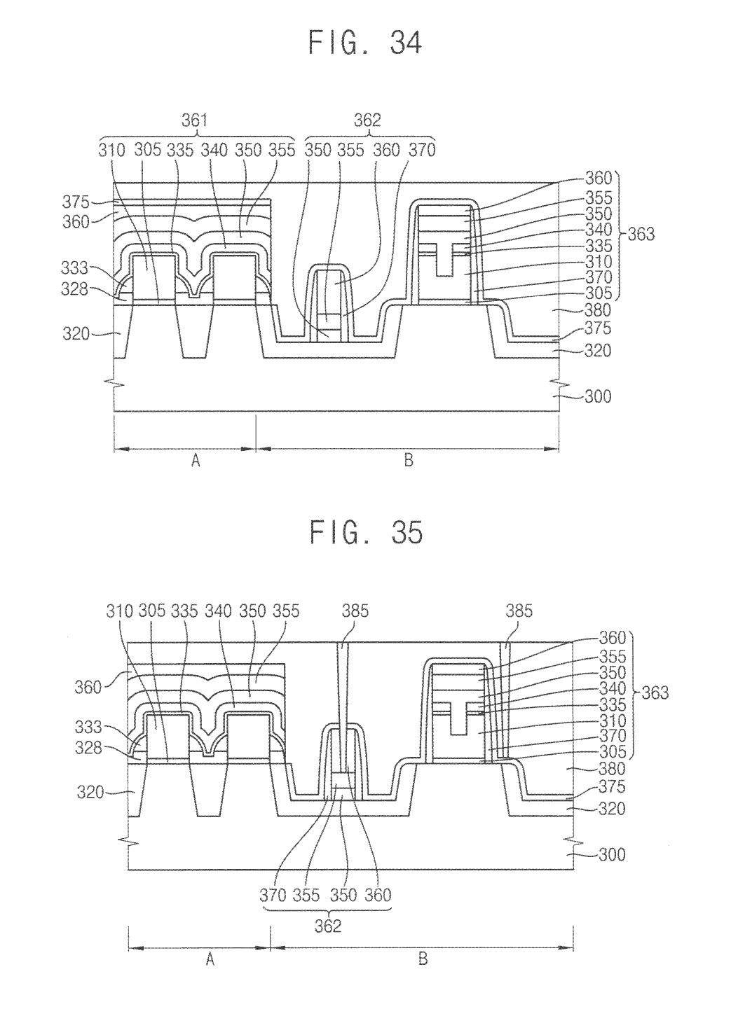

Referring to FIG. 34, an etch stop layer 375 is formed on the entire surface of the structures and the substrate 300. The etch stop layer 375 may be formed using nitride. The etch stop layer 375 may be formed to have thickness of from 200 Å to 500 Å. The etch stop layer may be used as a stop layer during a following process of forming a contact hole.

An insulation interlayer 380 is formed on the etch stop layer 375. Although the insulation interlayer 380 has a single layer structure as illustrated in the figure, the insulation interlayer 380 may have a multi layer structure of al least two layers formed by a HDP CVD process. The insulation interlayer 380 may be formed to fill a space between the structures by a HDP CVD process without void. In this embodiment, a first HDP CVD process may be performed to form a first preliminary insulation interlayer having a thickness of about 2,000 Å and then a wet etch process may be performed to partially etch the preliminary insulation interlayer. Then, a second HDP CVD process may be performed to form a second preliminary insulation interlayer having a thickness of about 2,000 Å and then a CMP process may be performed on the second preliminary insulation interlayer to form the insulation interlayer 380. Although it is not illustrated in the figure, an interlayer capping layer, an organic layer and anti-reflective layer may be formed on the insulation interlayer 380.

Referring to FIG. 35, a photolithography process is performed to form a metal contact hole in the insulation interlayer 380. A metal contact plug 385 is formed to fill the metal contact hole. The metal contact plug 385 may include aluminum, tungsten, copper, etc. The processes of forming the contact hole and filling the metal material may be selected according to characteristics of the device and the selected metal material.

Although one metal contact plug 385 is illustrated in the figure, a plurality of dummy contacts may be formed as described in Embodiment 2.

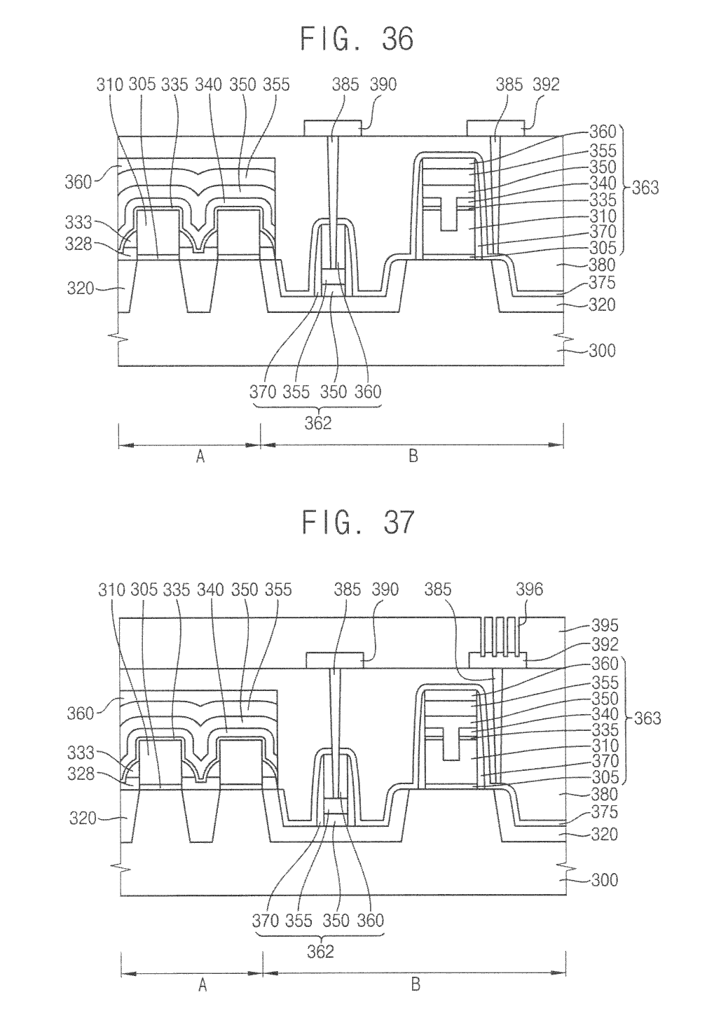

Referring to FIG. 36, an upper metal wiring 390 and a metal pad 392 are formed on the metal contact plugs 385, respectively. The metal pad 392 may be formed to have thickness of from 5,000 Å to 10,000 Å. Similarly to Embodiment 2, the metal contact plug 385 may be filled with tungsten and the metal pad 392 may be formed using aluminum such that an alloy layer is formed in the interface between the metal contact plug and the metal pad to increase adhesive strength therebetween.

Referring to FIG. 37, a photoresist layer is formed on the insulation interlayer 380, the metal wiring 390 and the metal pad 392, and then, is partially patterned to form a slit mask pattern 395 for forming slits 396 in the metal pad 392.

The metal pad 392 is etched using the slit mask pattern 395 as an etching mask to form a plurality of slits 396 in the metal pad 392. The plurality of the slits 396 may form grooves in the metal pad 392. The height of the slit may range from 3,000 Å to 5,000 Å. The time of etching the metal pad 392 may be controlled such that the slits do not extend beyond the middle portion of the metal pad 392. As a depth and a width of the slit 396 are increased, effects of anti-peeling off may be increased while dimensions of the contact area with the metal pad may be reduced to affect maximization of resistances and bonding areas. Accordingly, the etching time may be determined, considering the effects by the depth of the slit.

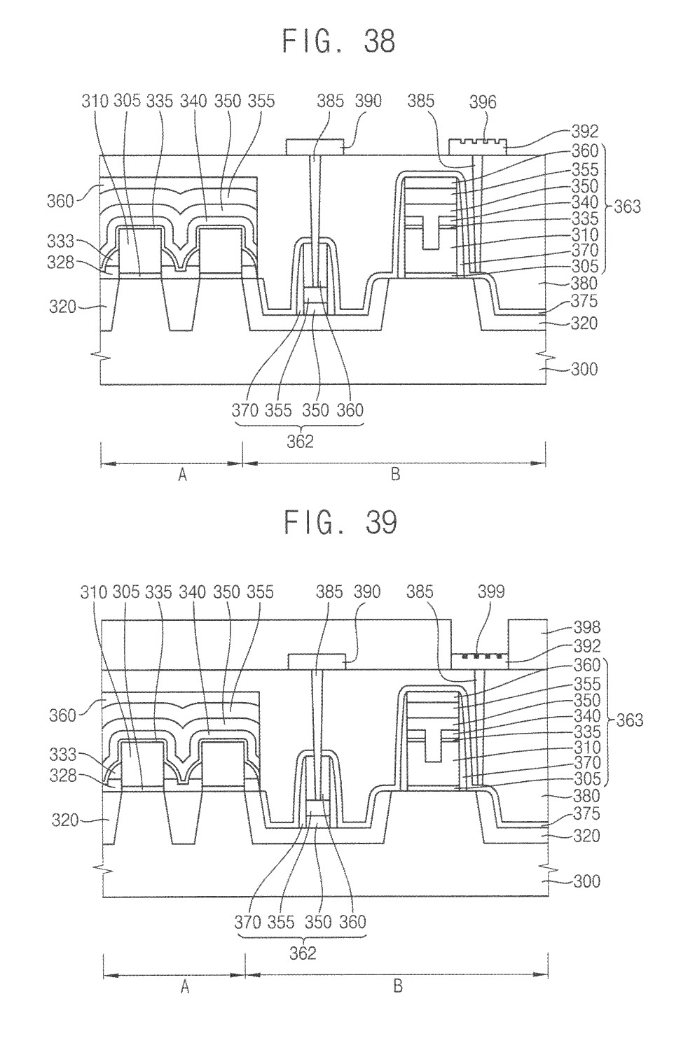

Referring to FIG. 38, after forming the slits 396, the slit mask pattern 395 is removed from the substrate. The plurality of the slits 396 are formed in an upper portion of the metal pad 392 and the metal contact plug 385 is vertically combined with a lower portion of the metal pad 392.

Referring to FIG. 39, a protecting layer 398 is formed on the insulation interlayer 380, the upper metal wiring 390 and the metal pad 392. The protecting layer 398 may have a single layer structure or a multi layer structure.

A photoresist layer is coated on the protecting layer 398 and patterned to form a bonding pad mask (not illustrated) that exposes only the region for a bonding pad to be formed. The protecting layer 398 is partially removed using the bonding pad mask. In here, the protecting layer may be etched such that a portion of the protecting layer 399 remains in the slits 396 of the metal pad 392.

The bonding pad including the protecting layer 399 remaining in the slits 396 may have a physical structure capable of preventing peeling-off of the metal pad 392.

As mentioned above, after forming the metal pad 392, the slits 396 are formed in the metal pad 392 by an etch process using the slit mask pattern 395 as an etching mask. Then, after forming the protecting layer 398, the residual protecting layer pattern 399 is formed in the slits during the process of etching the protecting layer.

The metal pad structure including the residual protecting layer pattern with a protruding shape is different in various aspects from a related art metal pad structure where the metal pad is prevented from peeling off by the protecting layer pattern formed on the metal pad. In particular, the slits are formed in the metal pad and the protecting layer filling the slits is removed to form the residual protecting layer pattern such that the upper surface of the residual protecting layer pattern has the same height as the upper surface of the metal pad. Accordingly, the residual protecting layer pattern may not make troubles during a following bonding process.

Further, since the residual protecting layer pattern in the slits of the metal pad includes a material different from the metal pad, the residual protecting layer pattern may buffer when physical impacts are generated or may terminate cracks generated in the metal pad.

The metal pad structure according to a third example embodiment may more effectively prevent peeling-off of the metal pad than a related art metal pad structure.

The residual protecting layer pattern 399 in the slits may overcome stresses applied to the metal pad during a bonding process together with the main protecting layer 398, thereby preventing peeling-off of the metal pad. Further, the residual protecting layer pattern including a material different from the metal pad may terminate crack generated in the metal pad.

The slits may be formed to have the same shapes as illustrated in FIGS. 10 to 12 in Embodiment 1.

As described herein, the processes of forming the slits in the metal pad are mainly explained for clarity, however, the present invention may be embodied in many different metal layer or processes and should not be construed as limited to the exemplary embodiments set forth herein.

Further, the present invention may be embodied in other processes in a combination of Embodiment 1 and Embodiment 2.

As mentioned above, a plurality of the slits are formed in the metal pad and the protecting layer pattern is formed in the slits. The protecting layer pattern is connected to the main protecting layer, to provide a semiconductor device having an anti-pad peeling-off structure.

In processes for forming DRAM, SRAM, NAND, NOR flash or logic devices, the cell having the pad structure may be easily formed.

The slits may be easily formed in the metal pad at once by a photolithography process.

A vertical-type transistor in accordance with some exemplary embodiments may be used as a selection transistor for various memory devices. Further, a vertical-type transistor in accordance with some exemplary embodiments may be positively applied for a semiconductor device to be highly integrated and having a relatively rapid operating speed.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and aspects of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed example embodiments, as well as other exemplary embodiments, are intended to be included within the scope of the appended claims.

1.-7. (canceled)

8. A semiconductor device, comprising:
a dielectric layer disposed on a semiconductor substrate;
a plurality of gate electrodes disposed on the dielectric layer;
an insulation interlayer disposed on the gate electrodes;
a metal wiring and a metal pad disposed on the insulation interlayer, wherein the metal pad comprises a plurality of slits; and
a protecting layer pattern that covers the metal wiring and exposes the metal pad such that portions of the protecting layer pattern are formed in the plurality of slits.

9. The semiconductor device of claim 8, wherein the gate electrodes comprise a plurality of redundant electrode patterns that form a concavo-convex structure under the metal pad.

10. The semiconductor device of claim 8, wherein the portions of the protecting layer pattern formed in the plurality of slits are connected to the protecting pattern covering the metal wiring such that the metal pad is prevented from being peeling off.

11. The semiconductor device of claim 8, wherein the plurality of slits form grooves such that the plurality of slits do not to extend beyond a middle portion of the metal pads.

12. The semiconductor device of claim 8, wherein the metal pad has an upper surface that is coplanar with an upper surface of the protecting layer pattern in the plurality of slits.

13. A semiconductor device, comprising:
a plurality of memory cells disposed in a cell region of a semiconductor substrate;
a plurality of peripheral circuit elements disposed in a peripheral region of the semiconductor substrate;
an insulation interlayer disposed on the plurality of memory cells and the peripheral circuit elements;
a plurality of metal contacts disposed in the insulation interlayer;
a metal wiring and a metal pad disposed on the insulation interlayer, the metal pad comprising a plurality of slits; and
a protecting layer pattern that covers the metal wiring and exposes the metal pad such that portions of the protecting layer pattern are disposed in the plurality of slits.

14. The semiconductor device of claim 13, wherein the plurality of memory cells are of a NAND flash structure.

15. The semiconductor device of claim 13, wherein the protecting layer pattern comprises a nitride layer.

16. The semiconductor device of claim 13, wherein the plurality of memory cells are of a DRAM structure.

17. The semiconductor device of claim 13, wherein end portions of said portions of the protecting layer pattern formed in the plurality of slits are connected to the protecting pattern that covers the metal wiring such that the metal pad is prevented from being peeling off.

18. The semiconductor device of claim 13, wherein the protecting layer pattern comprises a protruding portion extending from the protecting pattern that covers the metal wiring such that one end portion of the protecting layer pattern is connected to the protecting pattern that covers the metal wiring, thereby preventing the metal pad from being peeling-off.

19. The semiconductor device of claim 13, wherein end portions of said portions of the protecting layer pattern in the plurality of slits are connected to the protecting layer that covers the metal wiring to have an H-shape such that the metal pad is prevented from being peeling off.

20. The semiconductor device of claim 13, wherein the plurality of memory cells are of a silicon-oxide-nitride-oxide-silicon (SONOS) NAND structure.

21-27. (canceled)
